(19) United States
(12) Patent Application Publication
(10) Pub. No.: US 2010/0066383 A1
(43) Pub. Date: Mar. 18, 2010

(54) ARRAY SUBSTRATE AND DEFECT-DETECTING METHOD THEREOF

(76) Inventors: Te-Chen Chung, Kun Shan (CN); Tean-Sen Jen, Kun Shan (CN); Yu-Wen Chiu, Kun Shan (CN); Chia-Te Liao, Kun Shan (CN)

Correspondence Address: Nixon Peabody LLP, 200 Page Mill Road, Suite 200, Palo Alto, CA, 94306, US

(21) Appl. No.: 12/342,048

(22) Filed: Dec. 22, 2008

(30) Foreign Application Priority Data
Sep. 12, 2008 (CN) 200810212086.9

(51) Int. Cl. G01R 31/08; G01R 31/00

(52) U.S. Cl. 324/512; 324/770

(57) ABSTRACT

The present invention discloses an array substrate and a defect detecting method thereof. The array substrate comprises one or more shorting bars for applying signals to a plurality of data lines or a plurality of gate lines of the array substrate while testing. The array substrate further comprises a line detecting circuit for receiving signals on the plurality of data lines or the plurality of gate lines, and detecting and locating the line defects of the plurality of data lines or the plurality of gate lines. The array substrate and the defect detecting method thereof provided by the invention can locate the line defects of the array substrate accurately and quickly.

### CROSS REFERENCE TO RELATED APPLICATIONS

This application claims the priority of Chinese Patent Application No. 200810212086.9 filed on Sep. 12, 2008, which is hereby incorporated in its entirety by reference.

### FIELD OF THE INVENTION

The invention relates to a liquid crystal display, and in particular, to an array substrate and a defect-detecting method thereof.

### BACKGROUND

Liquid crystal displays (LCDs) have found wide applications due to their advantages such as light weight, thin profile, portability, environmental protection, etc. In general, a liquid crystal display comprises an array substrate and a color filter substrate that are oppositely set, and a liquid crystal layer sandwiched between the two substrates. The array substrate includes a plurality of gate lines and a plurality of data lines which are arranged in an orthogonally crossing manner to define a plurality of pixel regions, and thin film transistors (TFTs) for controlling the pixel are provided at the crossings of the gate lines and data lines. During manufacture, signal line defects (referred to as “line defects” hereinafter), such as shorting, opening, and so on, can occur in the plurality of gate lines and data lines due to defects in processing, thereby forming display defects in liquid crystal panels. It is desirable to repair the defects of the liquid crystal panels as much as possible to reduce production cost and increase quality.

In particular, the line defects of the array substrate can be detected first. A frequently used method for detecting line defects is to dispose a detecting circuit at the periphery of the array substrate (i.e., in an empty area other than the array substrate of a mother glass substrate) to perform detection, for example, shorting-bar test and the like. FIG. 1 is a schematic diagram of a conventional array substrate disposed with shorting bars. An array substrate of m rows and n columns is shown in FIG. 1, and a first gate shorting bar 11, a second gate shorting bar 12, a first data shorting bar 13 and a second data shorting bar 14 (two gate shorting bars and two data shorting bars are used here for the purpose of testing the odd and even gate/data lines respectively, and there certainly are other manners of locating the shorting bars) are disposed at the periphery of the array substrate. While testing, TFTs (not shown in FIG. 1) are turned on, scanning signals are applied to the odd and even gate lines via the first and the second gate shorting bars 11, 12 respectively, and data signals are applied to the odd and even data lines via the first and the second data shorting bars 13, 14 respectively. Thereby, the pixels connected to the data lines are driven, and then bright lines or similar defects are checked by visual inspection (generally, we could substantially determine the existence of line defects in the gate lines if there is a bright line in a certain row, and determine the existence of line defects in the data lines if there is a bright line in a certain column). If there are defects, the array substrate is moved to a detecting platform to determine the specific positions of the line defects. A frequently used method comprises: using a testing probe to contact the pin of a gate line or a data line to introduce testing signals, and then determining testing results in accordance with the outputted image signal. That is, the positions of line defects are determined by inspecting the outputted image signal corresponding to each data line with human eyes too. However, as the size of the liquid crystal panels increases, this detecting method is not adequate because it is time consuming, which can reduce production speed and there is a risk of human error for the visual inspection.

Therefore, an array substrate and a defect-detecting method thereof is needed in which the positions of line defects can be determined accurately and quickly, so as to perform the corresponding repairing.

### SUMMARY OF THE INVENTION

Embodiments of the invention provide an array substrate and a defect-detecting method thereof so as to locate the line defects on the array substrate accurately and quickly.

In accordance with one embodiment of the invention, there is a detecting apparatus of an array substrate, wherein the array substrate has a plurality of data lines and a plurality of gate lines, wherein the array substrate further comprises a line detecting circuit for receiving signals on the plurality of data lines or the plurality of gate lines, and detecting and locating the line defects of the plurality of data lines or the plurality of gate lines.

In accordance with another embodiment of the invention, there is a detecting method of an array substrate A defect detecting method of an array substrate comprises: applying signals to a plurality of data lines and a plurality of gate lines of the array substrate; determining whether there are line defects in the plurality of data lines or the plurality of gate lines; and detecting and locating the line defects of the plurality of data lines or the plurality of gate lines using a line detecting circuit if there are line defects.

### BRIEF DESCRIPTION OF THE DRAWINGS

The above and further advantages and features of the invention may be better understood by referring to the following description in conjunction with the accompanying drawings in which like reference numbers indicate identical or similar elements, and wherein:

FIG. 1 is a schematic diagram illustrating a conventional array substrate disposed with shorting bars;

FIG. 2 is a schematic diagram illustrating an array substrate that is provided with a data line detecting circuit in accordance with a first embodiment of the invention;

FIG. 3 is a schematic diagram illustrating a part of the data line detecting circuit in accordance with the first embodiment of the invention;

FIG. 4 is a waveform diagram illustrating the respective input signals of the data line detecting circuit in accordance with the first embodiment of the invention;

FIG. 5 is a schematic diagram illustrating another part of the data line detecting circuit in accordance with the first embodiment of the invention;

FIG. 6A is a flowchart illustrating a data line detecting method performed with the data line detecting circuit in accordance with the first embodiment of the invention;

FIG. 6B is a flowchart illustrating the procedure of detecting and locating the line defects performed with the data line detecting circuit in accordance with the first embodiment of the invention;

FIG. 7 is a schematic diagram illustrating an array substrate that is provided with a gate line detecting circuit in accordance with a second embodiment of the invention; and

FIG. 8 is a schematic diagram illustrating an array substrate that is provided with a data line detecting circuit and a gate line detecting circuit in accordance with a third embodiment of the invention.

### DETAILED DESCRIPTION OF THE INVENTION

The embodiments of the invention will be described in detail below with reference to the accompanying drawings.

### The First Embodiment

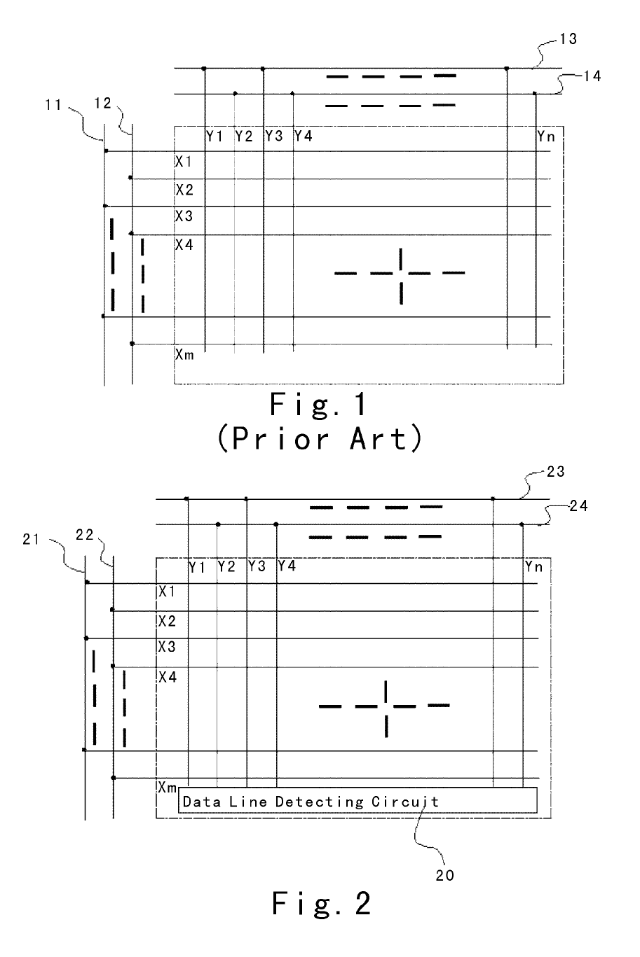

The first embodiment of the invention will be described first with reference to FIGS. 2 to 6B. FIG. 2 is a schematic diagram illustrating an array substrate that is provided with a data line detecting circuit in accordance with a first embodiment of the invention. The array substrate has m rows and n columns, and comprises at the periphery thereof (i.e., in an empty area other than the array substrate of a mother glass substrate) the following: a first gate shorting bar 21 electrically connecting with the odd gate lines (X1, X3, . . . , Xm-1), a second gate shorting bar 22 electrically connecting with the even gate lines (X2, X4, . . . , Xm), a first data shorting bar 23 electrically connecting with the odd data lines (Y1, Y3, . . . , Yn-1), and a second data shorting bar 24 electrically connecting with the even data lines (Y2, Y4, . . . , Yn). The array substrate of the first embodiment further comprises a data line detecting circuit 20 set in the non-display area of the lower part of the array substrate for receiving the voltage signals transmitted by all of the data lines Y1 to Yn. While testing, TFTs (not shown in FIG. 1) are turned on, scanning signals are applied to the odd and even gate lines via the gate shorting bars 21 and 22 respectively, and data signals are applied to the odd and even data lines via the data shorting bars 23 and 24 respectively (the data line detecting circuit 20 does not operate at that time). Thereby, the pixels connected to the data lines are driven, and then, whether there are bright lines or the like defects is checked by visual inspection. After confirming the existence of line defects, the data line detecting circuit 20 will be launched to accurately detect and locate the line defects. The specific principles thereof will be described in detail below (please note that in fact, in the embodiment, the step of “visual inspection” may be omitted and the line defects may be detected and located directly by the data line detecting circuit 20).

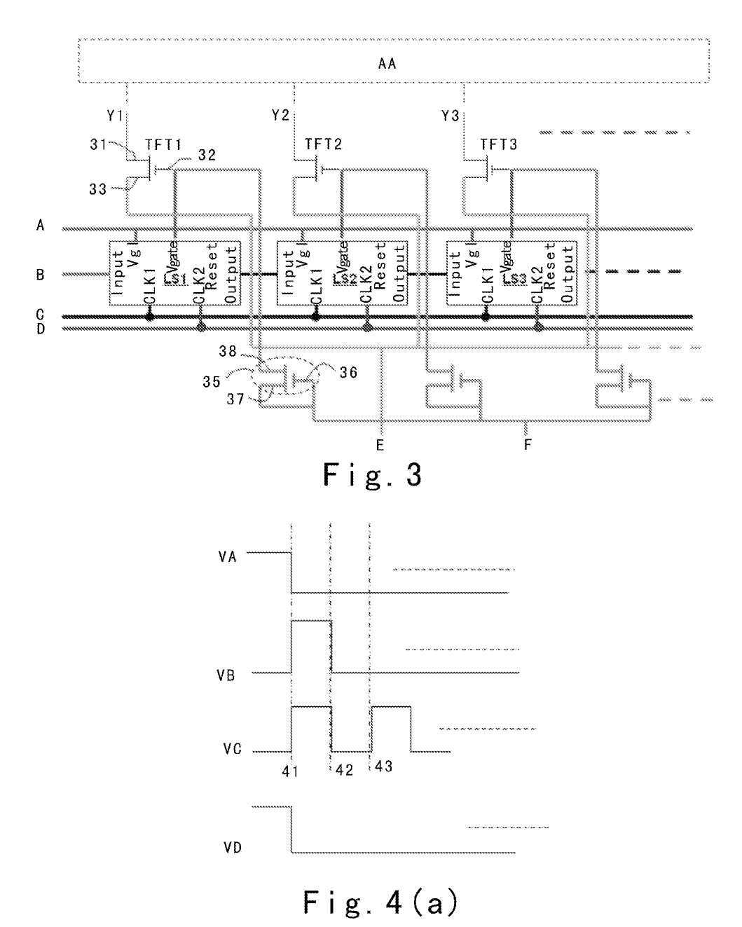

The principles of the data line detecting circuit in accordance with the first embodiment of the invention will be described in detail below with reference to FIGS. 3, 4 and 5. FIG. 3 is a schematic diagram illustrating a part of the data line detecting circuit as shown in FIG. 2. In FIG. 3, for the sake of clarity, the display area of the array substrate is denoted by a dashed block AA. As shown in FIG. 3, the data line detecting circuit comprises a plurality of switching elements and a plurality of level shifters (simply referred to as LS), wherein the level shifters constitute a shift register. In the embodiment, the switching elements are TFTs, and the numbers of the TFTs and the level shifters are each set to n corresponding to the number of data lines. In fact, however, depending on the requirements of design and test, other numbers of the switching elements and the level shifters may be used, the TFTs or the level shifters may be replaced with other elements, or the entire shift register may be replaced with other elements (for example, a multiplexer).

In the embodiment, as shown in FIG. 3, the data line detecting circuit comprises a plurality of TFTs (TFT1 to TFTn, but only TFT1 to TFT3 are shown in FIG. 3 for the purposes of clarity and ease of illustration) and a plurality of level shifters (LS1 to LSn, but only LS1 to LS3 are shown in FIG. 3 for the purposes of clarity and ease of illustration), wherein the n level shifters constituting a shift register. Each of the data lines (n data lines in total, Y1 to Yn) is connected to the source electrode 31 of a corresponding TFT. For example, the data line Y1 is connected to the source electrode of TFT1, the data line Y2 is connected to the source electrode of TFT2, . . . , and the data line Yn is connected to the source electrode of TFTn. Each TFT is configured to receive a control signal (Vgate) from a corresponding level shifter at its gate electrode 32, and is turned on or turned off under the control of Vgate so as to function as a switch. The drain electrodes 33 of TFT1 to TFTn are each connected to a signal output terminal E. The n level shifters are connected in series: the output terminal of LS1 is connected to the input terminal of LS2, the output terminal of LS2 is connected to the input terminal of LS3, . . . , and the output terminal of LSn-1 is connected to the input terminal of LSn. Each of the level shifters as shown in FIG. 3 can receive an input signal Input, a control signal Vgl, a reset signal Reset and clock signals CLK1 and CLK2, and can output a control signal Vgate and an output signal Output. The input signal Input of LS1 is provided by a terminal B, the input signal Input of LS2 is provided by the output signal Output of LS1, . . . , and the input signal Input of LSn is provided by LSn-1. The control signal Vgl of the n level shifters is provided by a terminal A, and the clock signals CLK1 and CLK2 are provided by terminals C and D respectively. Furthermore, although FIG. 3 does not show how the reset signal Reset of the n level shifters is provided, the reset signal can be controlled in accordance with requirements in order to reset the level shifters. One way is to provide a reset signal when the level shifters are powered on and not remove the reset signal until the power supply is stabilized. It is noted that in FIG. 3, the gate electrodes 32 of the n TFTs can further receive signals from a terminal F, for example, via respective n transistors (such as TFTs, diodes, and so on) which are TFTs 35 in the embodiment. As can be seen, the gate electrodes 36 of the TFTs 35 receive signals from the terminal F, the drain electrode 37 and gate electrode 36 of each TFT 35 are shorted, and the source electrodes 38 of the TFTs 35 are respectively connected to the corresponding gates 32 of TFT1 to TFTn. This configuration mainly considers the following: in the module stage for manufacturing a liquid crystal panel, since the data line detecting circuit has not been cut from the liquid crystal panel, after the module stage is completed, in order that the normal display of the liquid crystal panel is not affected by external signals via the data line detecting circuit, the terminal F will be inputted with a control signal Vgl which is transmitted to the gate electrodes of corresponding switching elements TFT1 to TFTn via respective TFTs 35, so as to turn off the switching elements TFT1 to TFTn finally, thereby separating the data lines (Y1 to Yn) from the data line detecting circuit.

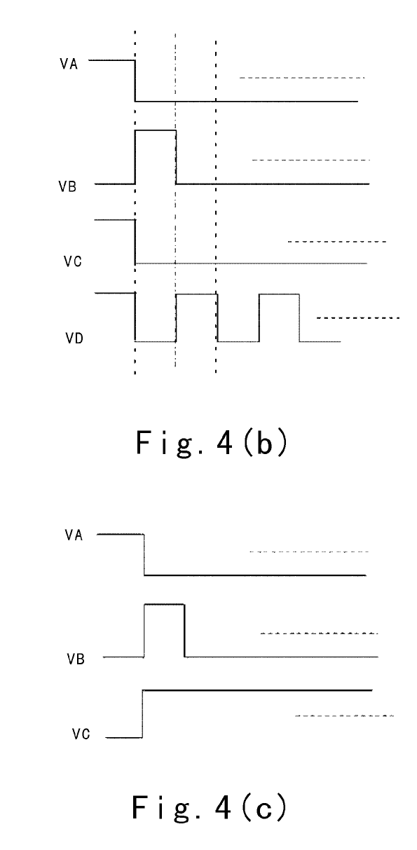

While testing, the corresponding data lines are driven (that is, the corresponding data lines are inputted with voltage signals via the data shorting bars), and the four terminals for testing signals, A, B, C and D in the data line detecting circuit are inputted with signals (denoted by VA, VB, VC, and VD respectively). FIGS. 4(a), 4(b), and 4(c) are waveform diagrams illustrating the respective input signals. VB is a start-up signal, which will start up the level shifter connected thereto (i.e., LS1) when it is a high level. VC and VD are clock signals (i.e., CLK1 and CLK2), in accordance with which the respective level shifters operate. VA is a control signal Vgl, and will turn on the switching element connected with a level shifter by controlling the terminal Vgate when it is a low level and the level shifter operates, whereby the voltage signal of a corresponding data line is outputted to the terminal E. The output voltage signal is denoted by “VE”.

In the following, description will be made to the example of testing the odd data lines, that is, inputting voltage signals to the odd data lines via an odd shorting bar. As shown in FIG. 4(a), since the odd data lines are being tested, the clock signal VD is always at a low level after the test begins. At the first rising edge of the clock signal VC (at the time 41), VB is inputted with a high level, and thereby LS1 operates (in the embodiment, supposing the level shifters operate when the input is a high level). At that time, VA is at a falling edge, that is, VA will transit to a low level after the time 41, whereby the Vgate under the control of VA turns on the TFT1, and the voltage signal on the data line Y1 reaches the terminal E via TFT1. That is, the signal of the terminal E at that time is the voltage signal on the data line Y1. Meanwhile, LS1 generates an output signal Output of a high level.

Then, at the falling edge of the clock signal VC (at the time 42), LS2 receives the high level from LS1 and enters an operating state (at the time, LS1 stops operating since VB has changed to a low level, and therefore the voltage signal on the data line Y1 will not be outputted to the terminal E via TFT1). However, VC will change to a low level after the time 42, so LS2 actually does not operate (LS2 only generates an output signal Output of a high level). Next, at the second rising edge of the clock signal VC (at the time 43), LS3 receives a high level from LS2, entering an operating state (both LS1 and LS2 do not operate at the time), and VC starts to enter a high level state, whereby the Vgate under the control of VA turns on TFT3 and the voltage signal on the data line Y3 reaches the terminal E via TFT3. That is, the signal of the terminal E at that time is the voltage signal on the data line Y3. Similarly, LS5, LS7, . . . , and LSn-1 will operate sequentially and the voltage signals on the data lines Y5, Y7, . . . , and Yn-1 will be outputted to the terminal E sequentially. In this case, the voltage signals on the odd data lines are outputted to the terminal E sequentially via the corresponding level shifters under the control of the clock signals VC and VD, thereby implementing the test of the odd data lines.

For testing the even data lines, voltage signals are inputted to the even data lines by an even shorting bar. As shown in FIG. 4(b), the test is similar to that of the odd data lines, except for the different controls by the clock signal VC and VD. That is, VC is always a low level after the test begins, and VD is a clock signal that changes between high and low levels periodically, whereby the voltage signals on the even data lines can be outputted to the terminal E sequentially via the corresponding level shifters, thereby implementing the test of the even data lines.

The invention is certainly not limited to the test of odd or even data lines. As an extension, the test could be performed without separating the odd and even data lines. For example, the test could be performed sequentially for all of the data lines Y1, Y2, Y3, . . . , Yn. In this case, only one input terminal (C or D) for clock signal is needed when designing the data line detecting circuit. Referring to FIG. 4(c), which is a waveform diagram of the input signals, while testing, VC, the input clock signal, remains in a high level, and the voltage signals on Y1, Y2 to Yn will be outputted to the terminal E sequentially in accordance with the sequential transmission of the signal of VB by LS1, LS2 to LSn, thereby implementing the test of all the data lines.

Therefore, through the subsequent actions of processing the signals outputted to the terminal E, defects of the respective data lines can be accurately detected and located.

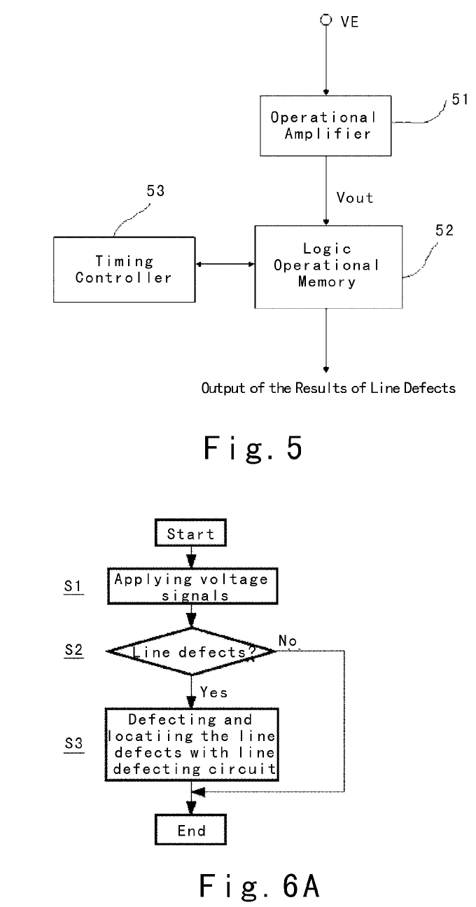

Reference will be made below to FIG. 5 to describe how to process the signal of the terminal E (VE) so as to detect and locate the defects of the corresponding data lines. FIG. 5 is a schematic diagram illustrating another part of the data line detecting circuit as shown in FIG. 2. In FIG. 5, the data line detecting circuit further comprises a signal processing unit, which can processes the signals sequentially outputted to the terminal E and locate the line defects. The signal processing unit comprises an operational amplifier 51, a logic operational memory 52, and a timing controller 53. However, in other embodiments, a modification, replacement, deletion and addition to these components can be made. For example, the signal VE may be processed directly without the operational amplifier, or a comparator may replace the logic operational memory, and so on. As shown in FIG. 5, firstly, the signal VE of the terminal E is inputted to the operational amplifier 51, which amplifies the signal VE and outputs the amplified signal Vout. Next, Vout is inputted into the logic operational memory 52. Typically, the logic operational memory 52 stores the corresponding output signal results (also referred to as normal output signal values) of the corresponding data lines in normal cases (that is, in non-defect cases). Under the control of the timing controller 53, the logic operational memory 52 can sequentially read the stored normal output signal values of the corresponding data lines, computes and compares the signal Vout with the normal output signal values, and outputs the results. The output results of the logic operational memory 52 can clearly and accurately show the data line(s) that has (have) defects, whereby the defects could be repaired in later processes.

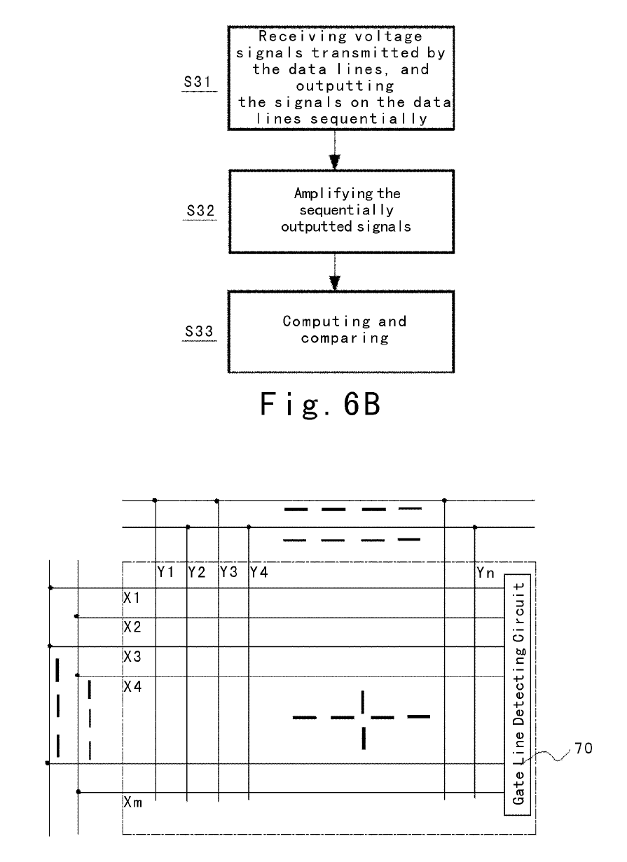

The data line detecting method of the invention will be described below with reference to FIGS. 6A and 6B. FIG. 6A is a flowchart illustrating the data line detecting method performed with the data line detecting circuit in accordance with the first embodiment of the invention. As shown in FIG. 6A, during detecting the data lines, firstly, in S1, voltage signals are applied to the gate lines X1 to Xm and the data lines Y1 to Yn of the array substrate via the shorting bars (21, 22 and 23, 24). Then in S2, the existence of line defects is determined by visual inspection for example. If it determines in S2 that there is no line defect, the detecting procedure ends. Otherwise, if it determines in S2 that there are one or more line defects, the detecting procedure proceeds to S3 (as described in detail below) in which the line defects of the data lines are detected and located using the data line detecting circuit.

FIG. 6B is a flowchart illustrating the procedure of detecting and locating the line defects (corresponding to S3 in FIG. 6A) performed with the data line detecting circuit in accordance with the first embodiment of the invention. As shown in FIG. 6B, in S31, the voltage signals of the corresponding data lines are received by the TFTs and level shifters shown in FIG. 3, and are outputted to the terminal E sequentially (VE). Then in S32, the signal VE received at the terminal E is amplified by the operational amplifier 51 shown in FIG. 5, and the amplified signal Vout is outputted. Then in S33, under the control of the timing controller 53, the logic operational memory 52 computes and compares the amplified signal Vout with the signals that are stored in the logic operational memory 52 in advance, and outputs the results of the computation and comparison (i.e., the results of line defects).

### The Second Embodiment

The above description is directed to an array substrate for detecting and locating line defects of data lines and the method thereof. For the gate lines, a similar gate line detecting circuit may be used to perform processing. Referring to FIG. 7, which is a schematic diagram illustrating an array substrate that is provided with a gate line detecting circuit 70 in accordance with the second embodiment of the invention. As shown in FIG. 7, the gate line detecting circuit 70 is set in the non-display area of the right part of the array substrate. The gate line detecting circuit 70 as shown in FIG. 7 can receive the voltage signals transmitted by the gate lines so as to detect and locate the line defects of the gate lines. The gate line detecting circuit 70 may have the same configuration as the data line detecting circuit of the first embodiment except connecting to m gate lines. In addition, the gate line detecting method that is performed with the gate line detecting circuit 70 of the embodiment may have the same flow as FIGS. 6A and 6B. Therefore, the detailed description on the gate line detecting circuit and the gate line detecting method of the present embodiment is omitted herein.

### The Third Embodiment

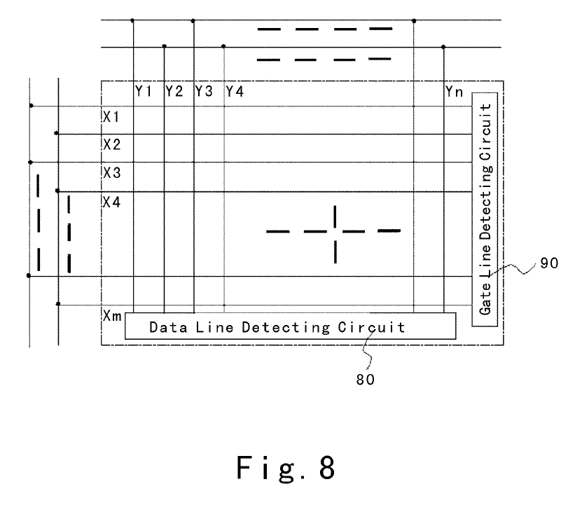

Other than providing only a data line detecting circuit or a gate line detecting circuit, a data line detecting circuit and a gate line detecting circuit may be provided simultaneously to detect the defects of the data lines and gate lines. FIG. 8 is a schematic diagram illustrating an array substrate that is provided with a data line detecting circuit and a gate line detecting circuit in accordance with the third embodiment of the invention. As shown in FIG. 8, a data line detecting circuit 80 and a gate line detecting circuit 90 are set in the non-display areas of the lower and right parts of the array substrate respectively. The data line detecting circuit 80 as shown in FIG. 8 can receive the voltage signals transmitted by the data lines so as to detect and locate the line defects of the data lines. The gate line detecting circuit 90 can receive the voltage signals transmitted by the gate lines so as to detect and locate the line defects of the gate lines. The data line detecting circuit 80 and gate line detecting circuit 90 of the present embodiment may have the same configurations as the data line detecting circuit 20 of the first embodiment and the gate line detecting circuit 70 of the second embodiment. In addition, the data line detecting method that is performed with the data line detecting circuit 80 of the embodiment may be the same as that of the first embodiment, and the gate line detecting method that is performed with the gate line detecting circuit 90 of the embodiment may be the same as that of the second embodiment. Therefore, the detailed description on the data line detecting circuit and the data line detecting method as well as the gate line detecting circuit and the gate line detecting method of the present embodiment is omitted herein.

There may be many other embodiments other than the above first to third embodiments. For example, one line detecting circuit may be used to detect the defects of both the data lines and gate lines by settings. The specific structure of the line detecting circuit may be altered in accordance with the requirements.

As can be seen from the embodiments of the invention, as compared with the conventional method of locating the line defects, the array substrate and defect detecting method provided by the invention are characterized in the following: by use of the added detecting circuit(s), the voltage signals of the corresponding signal lines are outputted sequentially, they are computed and compared with the stored voltage signals that are outputted in normal cases, and finally, the specific positions of the line defects can be obtained clearly and accurately, achieving the advantageous effect of reduced time consumption and automatic locating.

In the foregoing description, the specific embodiments of the invention are described with reference to the accompanying drawings. However, one ordinarily skilled in the art could understand that various modifications, combinations, alterations and replacements may be made to the specific embodiments of the invention without departing from the spirit and scope of the invention. Such modifications, combinations, alterations and replacements fall within the scope defined by the appended claims and its equivalents.

What is claimed is:

1. An array substrate comprises:
a plurality of signal lines; and
a line detecting circuit configured to receive signals on the plurality of signal lines, and detect and locate the line defects of the plurality of signal lines.

2. The array substrate of claim 1, wherein the line detecting circuit comprises:
a plurality of switching elements that connect to the plurality of signal lines respectively;
a shift register configured to control the plurality of switching elements sequentially and output the signals on the plurality of signal lines sequentially; and
a signal processing unit configured to process the sequentially outputted signals and finally locate the line defects.

3. The array substrate of claim 2, wherein the signal processing unit comprises:
an operational amplifier configured to amplify the sequentially outputted signals;
a timing controller; and
a logic operational memory, wherein
under the control of the timing controller, the logic operational memory is configured to compute and compare the signals stored in the logic operational memory with the signals amplified by the operational amplifier, and outputs the results of the computation and comparison.

4. The array substrate of claim 1, wherein the line detecting circuit is set in a non-display area around the array substrate.

5. The array substrate of claim 2, wherein the shift register comprises a plurality of level shifters connected in series, and the plurality of level shifters are configured to operate sequentially while detecting.

6. The array substrate of claim 2, wherein the plurality of switching elements are a plurality of thin film transistors.

7. The array substrate of claim 2, wherein the line detecting circuit further comprises a plurality of transistors configured to transmit a control signal to turn off the corresponding switching elements respectively.

8. The array substrate of claim 3, wherein the signals stored in the logic operational memory are output signals of the plurality of signal lines in cases of no line defects.

9. A defect detecting method of an array substrate comprising:
applying signals to a plurality of signal lines of the array substrate;
determining whether there are line defects in the plurality of signal lines; and
detecting and locating, by a line detecting circuit, the line defects of the plurality of signal lines when there are line defects.

10. The defect detecting method of an array substrate of claim 9, wherein the detecting and locating, by the line detecting circuit, the line defects of the plurality of signal lines comprises:
receiving the signals on the plurality of signal lines and outputting the signals on the plurality of signal lines sequentially;
amplifying the sequentially outputted signals;
computing and comparing the amplified signals and signals stored in advance; and
outputting the results of the computation and comparison.

11. The defect detecting method of an array substrate of claim 10, wherein the signals stored in advance are output signals of the plurality of signal lines in cases of no line defects.

12. A liquid crystal display comprising:
an array substrate;
a color filter substrate opposite to the array substrate; and
a liquid crystal layer sandwiched between the array substrate and the color filter substrate, wherein the array substrate comprises:
a plurality of signal lines; and
a line detecting circuit configured to receive signals on the plurality of signal lines, and detect and locate the line defects of the plurality of signal lines.

13. The liquid crystal display of claim 12, wherein the line detecting circuit comprises:
a plurality of switching elements connected to the plurality of signal lines respectively;
a shift register configured to control the plurality of switching elements sequentially and output the signals on the plurality of signal lines sequentially; and
a signal processing unit configured to process the sequentially outputted signals and finally locate the line defects.

14. The liquid crystal display of claim 13, wherein the shift register comprises a plurality of level shifters connected in series, and the plurality of level shifters are configured to operate sequentially while detecting.

15. The liquid crystal display of claim 13, wherein the plurality of switching elements are a plurality of thin film transistors.

16. The liquid crystal display of claim 13, wherein the line detecting circuit further comprises a plurality of transistors configured to transmit a control signal to turn off the corresponding switching elements respectively.

17. The liquid crystal display of claim 13, wherein the signal processing unit comprises:
an operational amplifier configured to amplify the sequentially outputted signals;
a timing controller; and
a logic operational memory, wherein
under the control of the timing controller, the logic operational memory is configured to compute and compare the signals stored in the logic operational memory with the signals amplified by the operational amplifier, and outputs the results of the computation and comparison.

18. The liquid crystal display of claim 12, wherein the line detecting circuit is disposed in a non-display area around the array substrate.
